(19) United States
(12) Patent Application Publication
(10) Pub. No.: US 2002/0196651 A1
(43) Pub. Date: Dec. 26, 2002

(54) Memory cell layout with double gate vertical array transistor

(76) Inventor: Rolf Weis, Wappinger Falls, NY (US)

Correspondence Address: Steven H. Slater, Slater & Matsil, L.L.P., Suite 1000, 17950 Preston Road, Dallas, TX, 75252, US

(21) Appl. No.: 09/888,202

(22) Filed: Jun. 22, 2001

(51) Int. Cl. H01L 21/8242; G11C 17/00

(52) U.S. Cl. 365/100; 438/243; 438/246; 257/302

(57) ABSTRACT

An 8F2 (2×2F wordline pitch by 2F bitline pitch) memory cell uses a vertical gate transistor having one gate driving two sources and two drains, one source and drain being formed on each side of the trench. Because two channels are provided, the device allows for sufficient current capacity, even with a 2F gate length. The memory cell array is formed in a series of active regions, corresponding to the bit lines of the array, which active regions are bounded by isolation trenches between the bit lines. The deep trenches segment the active regions and the overlying bit lines tie the cells of a given row together. Each memory cell has two drain regions, each having two contacts to the bit line and adjacent cells share one drain region, resulting in four contacts to the bit line for each memory cell. Support circuitry, including sense amplifiers

### CROSS REFERENCE TO RELATED APPLICATION

This application is related to co-pending, co-assigned patent application, attorney docket number 01 P 11026 US, which application is incorporated herein by reference.

### FIELD OF THE INVENTION

This invention relates generally to trench DRAM architecture and more specifically to a trench DRAM cell and architecture employing a vertical gate transistor.

### BACKGROUND OF THE INVENTION

The primary driving motivator in commercial memory cells and architecture is the desire to pack more memory capability into a smaller integrated circuit. This goal necessarily involves competing trade-offs in cost, circuit complexity, power dissipation, yield, performance, and the like. Trench capacitors are known in the art as an architecture whereby the overall size (in terms of surface area or chip “real estate”) of the memory cell is reduced. The size reduction is accomplished by taking a planar capacitor element of the memory cell and forming the capacitor instead in a trench.

As is known in the art, a typical DRAM cell includes a capacitor upon which is stored a charge (or no charge depending upon the cell's state) and a pass transistor, which is used to charge the capacitor during writing and in the read process to pass the charge on the capacitor to a sense amplifier. In current manufacturing, planar transistors are used for the pass transistors. Such planar transistors have a critical dimension of gate length that cannot be shrunk below approximately 110 nm, while maintaining the on and off current required for DRAM retention (typically on the order of 40 μA for on current and 1 fA for off current at operational voltage). Below that size, the transistor performance becomes degraded and is very sensitive to process tolerances. As such, for DRAM cells that are desired to be shrunk below a roughly 110 nm ground rule, existing planar transistors cannot provide the performance necessary for proper DRAM cell operation. A need exists, therefore, for a DRAM memory cell employing a pass transistor architecture that maintains acceptable on current to off current ratios, even when shrunk to very small dimensions.

In addition to a vertical or trench capacitor, a vertical pass transistor has been proposed in the prior art. Reference is made to Ulrike Gruening et al., IEDM Tech. Dig., p. 25 (1999) and to Carl Radens et al., IEDM Tech. Dig. p. 51 (2000), which references are incorporated herein by reference, for further information regarding known vertical transistor technology. While known, the vertical cell transistors proposed to date suffer from various disadvantages, including process complexity and costs.

### SUMMARY OF THE INVENTION

In one aspect, the present invention provides for a memory device comprising a memory cell array. The array includes a plurality of memory cells arranged in rows and columns, the rows being separated by isolation trenches. Each memory cell comprises a trench having a capacitor formed therein, a first pass transistor having a first doped region formed from an outdiffusion of doped material formed within the trench, a second doped region formed adjacent the trench, a gate region formed within the trench, and a gate oxide formed on a sidewall of the trench. Each memory cell further comprises a second pass transistor having a first doped region formed from an outdiffusion of doped material from within the trench, and a second doped region formed adjacent the trench. The second pass transistor shares the gate region formed within the trench with the first pass transistor, and has a gate oxide formed on a sidewall of the trench.

In another aspect, the present invention provides for a method of forming a memory cell. The method comprises: forming a buried plate within a semiconductor substrate, forming a deep trench having sidewalls within an active area of a semiconductor substrate, forming an oxide along the sidewalls of the deep trench, and forming a trench collar along a lower portion of the deep trench. The method further comprises filling the trench partly with polysilicon, wherein the polysilicon is outdiffused into the active area from the trench in those portions not bound by the trench collar during subsequent processing steps. The method further comprises forming a trench top oxide on the polysilicon, filling the trench with a gate polysilicon above the trench top oxide, forming a first doped region adjacent one sidewall of the trench and a second doped region adjacent another sidewall of the trench, forming a contact to the gate polysilicon and connecting the gate polysilicon to a word line, and forming a contact to the first and second doped regions and connecting the first and second doped regions to a bit line.

In yet another embodiment, the invention provides for a memory circuit comprising a capacitor, the capacitor being formed in a lower portion of a trench. The circuit further comprises a logical pass transistor having a vertical gate formed within an upper portion of the trench, and comprising first and second source regions, first and second drain regions, and a single gate, having a first gate oxide adjacent the first source and drain regions and a second gate oxide adjacent the second source and drain regions.

In certain embodiments, the present invention provides for a high performance vertical transistor device (double gate) fulfilling DRAM on/off current requirements in a manner that is low cost, having an efficient layout that does not require an excessive number of lithographic steps. The structure is overlay insensitive through the use of line masks and the DT (deep trench) top structure.

The preferred embodiments of the present invention provide the advantage of a minimal cell area of a folded bitline cell that is shrinkable far below 100 nm.

### BRIEF DESCRIPTION OF THE DRAWINGS

The above features of the present invention will be more clearly understood from consideration of the following descriptions in connection with accompanying drawings in which:

FIGS. 1a and 1b illustrate in plan view a preferred embodiment memory architecture;

FIG. 1c schematically illustrates a memory cell;

FIG. 2 is cross section of a preferred embodiment memory cell, taken through the active region;

FIG. 3 is a cross section of a preferred embodiment memory cell taken perpendicularly to the axis of the active region;

FIGS. 4a through 4e illustrate process steps in fabricating preferred embodiment memory cells and arrays;

FIG. 5a and 5b provide plan view detail of a deep trench formed in the active region; and

FIGS. 6a through 6i illustrate additional process steps in fabricating preferred embodiment memory cells and arrays.

### DETAILED DESCRIPTION OF ILLUSTRATIVE EMBODIMENTS

The making and use of the various embodiments are discussed below in detail. However, it should be appreciated that the present invention provides many applicable inventive concepts, which can be embodied in a wide variety of specific contexts. The specific embodiments discussed are merely illustrative of specific ways to make and use the invention, and do not limit the scope of the invention.

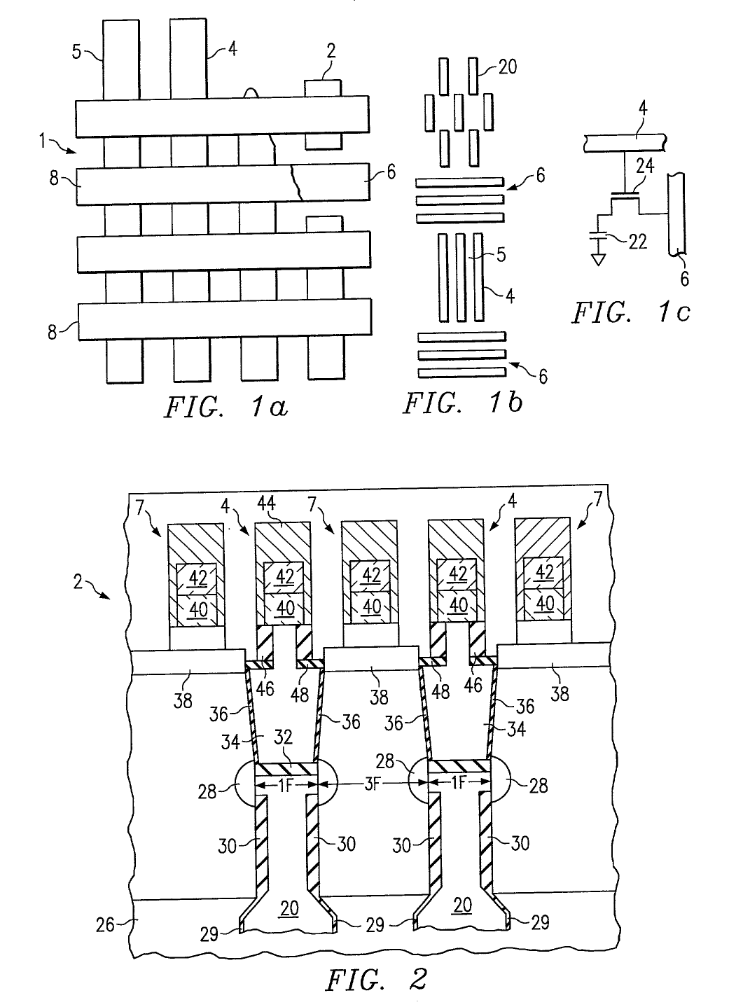

FIGS. 1a and 1b illustrate in plan view, a memory cell array comprised of the preferred embodiment memory cells. FIG. 1b shows the pattern of various features of the array separately and FIG. 1a shows the patterns of the features superimposed on one another. In other words, FIG. 1b represents the view of FIG. 1a at four different “depths.” The first pattern of FIG. 1b illustrates the arrangement of a series of deep trenches 20. The second pattern of FIG. 1b illustrates the arrangement of the active areas in which are formed doped junctions for the pass transistors, as discussed in greater detail below. The third pattern illustrates the gate contact patterns or word lines of the array and the fourth pattern illustrates the bit lines of the array. FIG. 1a shows these four patterns of features superimposed upon one another to form the memory cell array 1. The array 1 is comprised of a series of cells 2. Each cell is contacted by two word lines 4 and 5 and a bit line. The bit line is comprised of an active area (AA) region of silicon or polysilicon 6, to which is contacted a bit line 8 comprised of a metal like tungsten or highly doped poly. The word line contacts the gate of the pass transistor and the bit line contacts the drain, as will be described in greater detail below. Each AA region is electrically isolated from the next via an isolation trench (IT) 10, which is preferably a trench filled with a field oxide of about 500 nm in depth.

Each cell 2 comprises a deep trench (DT) region 20 wherein is formed the trench capacitor and the vertical transistor, as will be described in greater detail below. In the preferred embodiments, the deep trench is preferably about six microns in depth. Note that each deep trench interrupts the AA silicon regions that forms part of the bit line. As will be described in greater detail below, a bitline layer, contacts the AA region on each side of the deep trench, where the AA region forms the drain of the pass transistor for that memory cell. The word line 4 passes through the layer of the AA regions over the deep trench regions (i.e. where the AA region is interrupted) to contact the gate of the vertical transistor formed within the trench.

FIG. 1c provides a schematic illustration of a preferred embodiment memory cell 2. The cell comprises a charge storage capacitor 22 having one plate tied to a reference voltage (typically ground as shown in FIG. 1b or half of the bitline voltage) and having its other plate tied to the source of pass transistor 24. Pass transistor 24 has its drain tied to bit line 6 and its gate tied to word line 4, as is well known in the art. As will be described in greater detail below, in the preferred embodiments of the present invention, charge storage capacitor 22 is formed within deep trench 20 as is the source for pass transistor 24. Additionally, the gate of pass transistor is formed within the upper region of deep trench 20, above the trench top oxide (TTO). Another advantageous feature of the preferred embodiments is that the drain region for pass transistor 24 is formed on both sides of deep trench 20, thus providing twice the gate width as would be provided in prior art devices of comparable gate lengths.

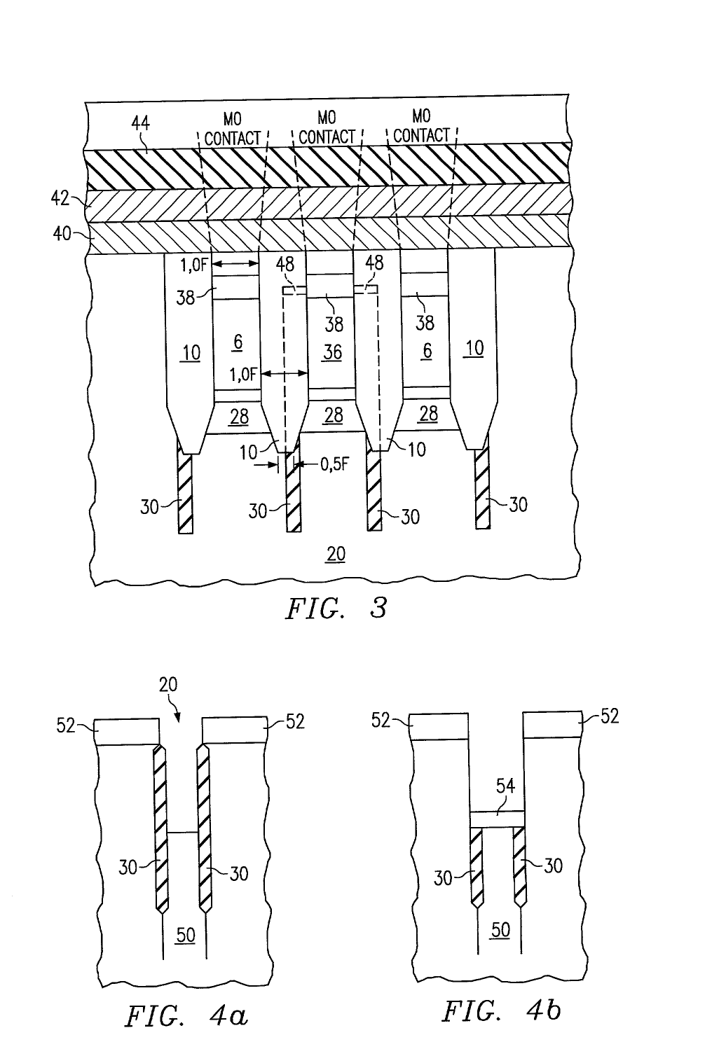

FIG. 2 provides a cross sectional illustration of a preferred embodiment memory cell 2 taken through the active region AA shown in FIG. 1. Storage capacitor 22 is formed within the deep trench 20. A buried plate or buried region 26 forms one plate of the capacitor. In the preferred embodiments, buried plate 26 is a heavily doped region, preferably N-doped, formed within a bulk p-type semiconductor substrate. Alternatively, of course, buried plate 26 could be a p-type regions formed within an n-type bulk substrate or within an n-type well formed within a p-type substrate. A thin dielectric layer such as of oxide or nitride or any combination of both or any other high-k material in region 28 formed around the periphery of deep trench 20 forms the capacitor dielectric and doped, preferred n-type poly formed within the lower region of deep trench 20 forms the other plate of storage capacitor 22. Deep trench 20 also comprises a heavily doped buried strap region 28, which forms a first doped junction for pass transistor 24 (referred to herein as the source). This buried strap is electrically connected to the n-doped poly formed within the lower region of the deep trench 20, thus forming the connection between pass transistor 24 and charge storage capacitor 22. Deep trench 20 also preferably comprises trench collar oxide 30 and trench top oxide 32, which prevent parasitic current leakages, as is well known in the art. In the preferred embodiments, the trench collar 30 extends to a depth of about 1.5 microns for a six micron deep trench, although the exact dimensions of the trench are a matter of design choice.

In addition to the buried strap source region 28, pass transistor 24 also includes doped gate poly 34, (preferably N-type, in other embodiments, P-type doping could be employed) formed within the upper region of deep trench 20 and gate oxide 36. Note that gate oxide 36 is formed on both sides around gate poly 34 in the upper part of trench 20. Pass transistor also includes drain region 38, which is formed on both sides of the trench as well. In this way the overall gate width is doubled for a given gate length, because the transistor provides for two source to drain paths—one on each side of the deep trench. Each drain region 38 is connected to the bit line 8 (not shown in FIG. 2) via bitline contacts 40. As shown in FIG. 2, the gate poly 34 is contacted by active word line 4. Note that other word lines are shown in FIG. 2. These word lines are connected to other memory cells, but not the memory cells being illustrated in FIG. 2. As such, those word lines 5 are referred to as passing word lines (PWL) as per FIG. 2, whereas the word line 4 contacting gate poly 34 is referred to as an active word line (AWL). In the preferred embodiments, the word lines 4 and 5 consist of a low resistive conductor layer on an optional barrier layer such as a dual layer conductor formed of a first WN or polysilicon/WN layer 140 over which is formed a tungsten or WSi layer 42. The conductive layers are surrounded by a nitride insulating layer 44 to insulate the word lines from MO contacts 40 and the bitline. Additionally, gate poly 34 is insulated from adjacent features, such as doped regions 38, by spacer 46 and cap 48. In the preferred embodiments, spacer 46 is formed of an oxide layer and cap 48 is formed of a nitride. Other materials could be substituted depending upon the process flow, provided adequate insulation is provided to gate poly 34. The passing wordline 5 is insulated from the doped regions 38 by an array top oxide (ATO). Note that, as illustrated in FIG. 1, word line 4 is the active word line for a given memory cell and word line 5 is the passing word line, but for an adjacent memory cell (in an adjacent row), word line 4 is the passing word line (i.e. no contact to the cell) and word line 5 is the active word line.

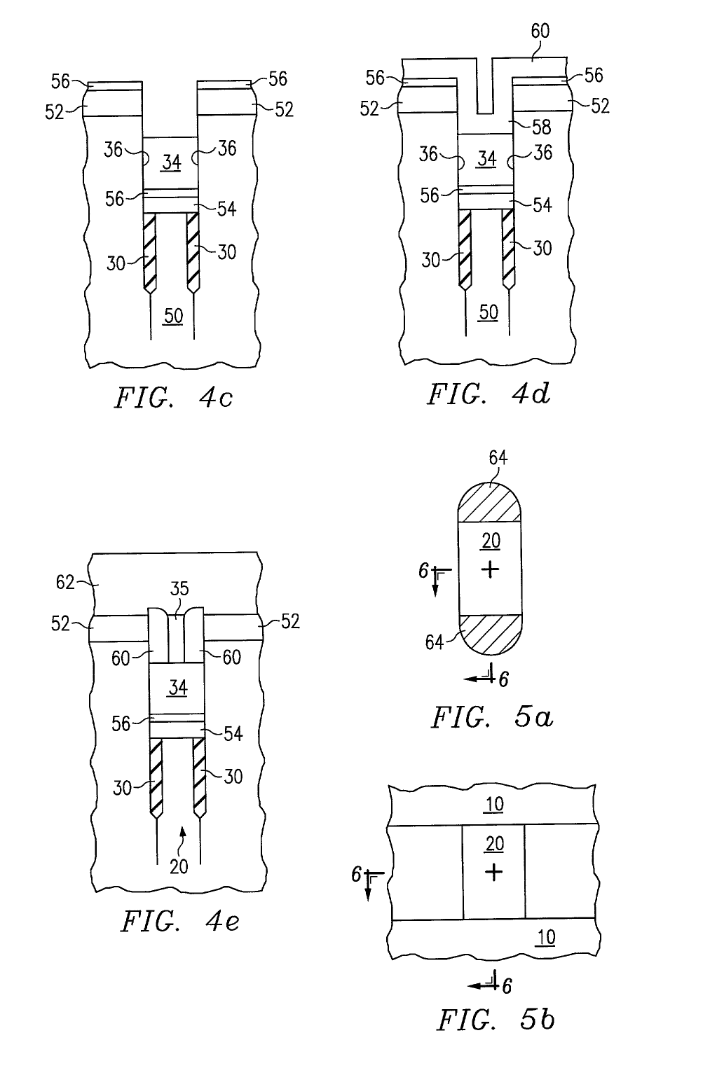

FIG. 3 provides a cross section of the memory cell 2 taken perpendicularly to FIG. 2, i.e. along the word line 5. The deep trench 20 is illustrated in the center of FIG. 3 as is the trench collar oxide region 30. Four isolation trenches 10 are also illustrated. Recall from FIG. 1 that the isolation trenches are formed between the active regions and separate the bit lines from one another. Going from left to right in FIG. 3, corresponding to going from top to bottom in FIG. 1 (along word line 5), one encounters first an isolation trench 10, followed by an active area region 6, followed by the deep trench region 20, then another isolation trench 10, another active region 6, and so on.

Buried strap region 28 is shown in phantom lines inside the deep trench region of FIG. 3 because the buried strap is actually out-diffused from the deep trench poly into the surrounding bulk region. This is illustrated by buried strap region being shown in the bulk silicon of active regions 6. Also shown is trench top oxide region 32 that is visible inside the deep trench 20, but is shown in phantom lines in the bulk silicon of the active regions 6. Likewise, doped drain junction 38 are shown in phantom lines in FIG. 3 because these features are behind or in front of the cross-section view being illustrated. Although the nitride cap 48 together with the upper part of the trench 20 are illustrated in the IT region 10, they were actually etched out in the IT etch step. The features are shown in the cross-section view FIG. 3 simply to illustrate the relative placement of the illustrated layers and features and to place the elements in context. Gate oxide 36 is parallel to the plane of the paper in the perspective of FIG. 3 and would not be visible in the actual cross section, but is also labeled for context. Finally, the word line is shown, comprising a poly layer 140, tungsten layer 42, and nitride cap 44. Also shown in phantom are the bitline contacts by which the bit line would contact drain regions 38.

Referring again to FIG. 2, note that each cell comprises two transistors. Each transistor shares a common gate poly 34, but there are two gate oxides 36, two sources or first doped junction regions 28, and two drains or second doped junction regions 38. This arrangement could also be thought of as a single logical transistor (operating under a single control signal), but having its source, gate oxide, and drain physically separated into two distinct regions. Note that each drain region 38 of each transistor has two contacts 40 to the bit line 6. The logical pass transistor hence has four contacts to the bit line. Note also that each logical pass transistor shares a common doped junction region (the drain region) 38 with a neighboring transistor. These features of the preferred embodiment provide several advantages. A first advantage is that only one mask (and hence one photolithography step) is needed for the bitline and the bitline contact. An additional advantage of this arrangement is the insensitivity of the contact resistance bitline to the transistor during misalignment of the wordline to the deep trench. If we assume a shift of all wordline in the direction parallel to the wordline compared to the DT poly gate and look at the connection of one gate on one side to the bitline, the contact area of the MO contact of one of the two contacts would be decreased and that of the other contact increased because the silicon area is changed with the overlap over the DT cap 48. As there is a connection between both contacts over the doped region 38, at least one of the contacts would make a good, low-resistance connection to the bitline. It is known that bitline capacitance performance can be improved by connecting the drains of two cells before connecting them to the bitline over one contact. In an alternative embodiment, one of the bitline contacts 40 could be masked off during the photolithography for forming the bit line. This would decrease the overall bit line capacitance, but requires additional photolithographic steps and is hence not a preferred embodiment.

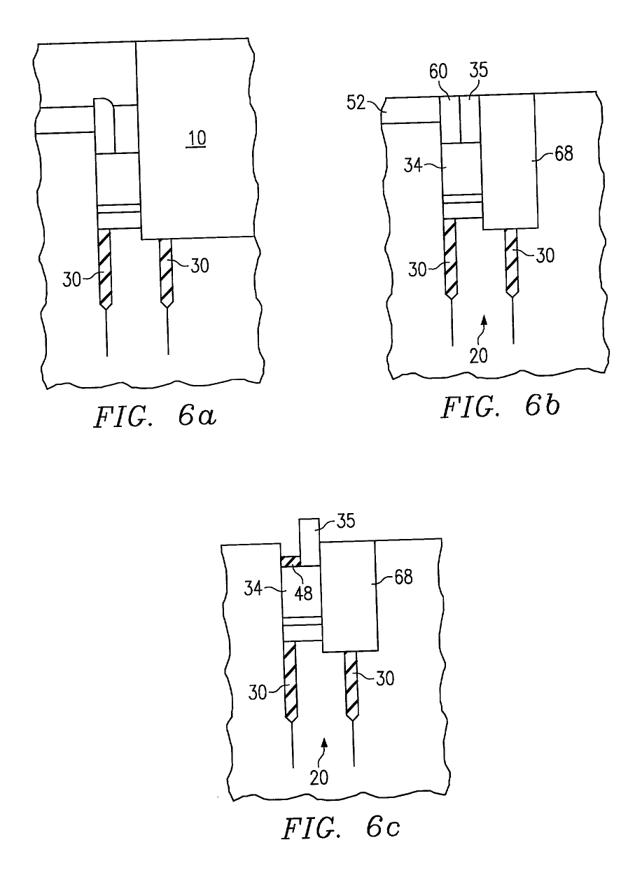

A preferred embodiment process flow for forming the above described memory cell is discussed with reference to FIGS. 4a through 4e, FIG. 5, and FIGS. 6a through 6i. In FIG. 4a, a deep trench 20 has been formed, trench collar oxide 30 has been formed and the trench has been filled with polysilicon 50 and the polysilicon 50 has been recessed back to a desired level within the trench, all as is well known in the art. Nitride layer 52 protects the surrounding silicon during the polysilicon etch step. As shown in FIG. 4b, the trench collar oxide is recessed back, preferably using a wet etch technique. The oxide recess will result in a divot where the collar oxide is removed below the level of polysilicon fill 50. An optional thin oxidation or nitridation can also be performed. The divot is filled in by re-filling the trench with polysilicon 54 and recessing the polysilicon 54 to the desired level, as shown. This polysilicon 54 can be either slightly doped or undoped poly and is preferably recessed using a standard RIE or wet etch technique. This polysilicon region 54 will subsequently be doped in high temperature steps by 50 and out-diffuse to form the buried strap region 28, as will be described below.

The formation of the trench top oxide 32 is now described with reference to FIG. 4c. This is accomplished by first forming a sacrificial oxide layer (not shown) on the sidewalls of the deep trench 20 (above the region of polysilicon 54). Trench top oxide layer 56 is then formed on the horizontal surfaces using an HDP process with a wet etch back. One skilled in the art will recognize that the HDP oxide deposition fills in from the bottom to the top in contrast to conformal deposition, where the oxide layer thickness is deposited uniformly. The HDP is deposited and than etched back by a wet chemistry. Due to the fact that the HDP oxide deposition covers the horizontal regions with a thicker deposition than the sidewalls, the sidewalls can be subsequently cleaned without etching away the oxide on horizontal areas. Preferably the resulting oxide layer thickness is around 30 nm. optionally, a nitride wet etch can be performed to remove the overhang of the nitride layer 52 in the trench 20. After formation of the TTO layer 56 the sacrificial oxide layer is removed, thus providing a clean deep trench sidewall surface for subsequent growing of the gate oxide 36. After gate oxide 36 has been formed, gate polysilicon 34 is deposited within the deep trench, polished by CMP and recessed. Preferably, the deep trench is overfilled with gate polysilicon followed by a chemical mechanical polish (CMP) to the top of nitride layer 52 or to TTO layer 56. The polysilicon is then etched to approximately 70 nm below the surface of the bulk silicon surrounding deep trench 20. The 70 nm recess is a matter of design choice, provided that the recess is within the junction depth of the drain 38 in order to ensure no overlap of the junction to the gate.]

As shown in FIG. 4d, the exposed surfaces of the bulk silicon and of gate polysilicon 34 are then oxidized forming oxide layer 58. Nitride liner 60 is then formed. Nitride liner 60 is preferably formed by a CVD deposition and is generally one third of the trench width. Although not illustrated, in some embodiments junction 38 extensions could be self-aligned implanted with an angle at this step as well. FIG. 4e illustrates the subsequent step in which the nitride liner is etched back to form the nitride spacer. This is followed by an oxide clean in which the oxide layer 58 is removed from the exposed surface of gate polysilicon 34 and also the TTO layer 56 formed atop nitride layer 52 is removed simultaneously if not stripped earlier. Additional polysilicon is deposited atop gate polysilicon 34, resulting in polysilicon stud 35 (which is preferably integral with gate polysilicon 34). Preferably the polysilicon stud layer 35 is overfilled and then wet etched back or alternatively subjected to a CMP planarizing step. A hardmask 62 is then deposited over the region to protect the trench during subsequent active area processing. Preferably, hard mask 62 is formed by TEOS deposition. Alternatively, the hardmask could be formed by BSG or other doped oxide or Silicon etch hardmask material.

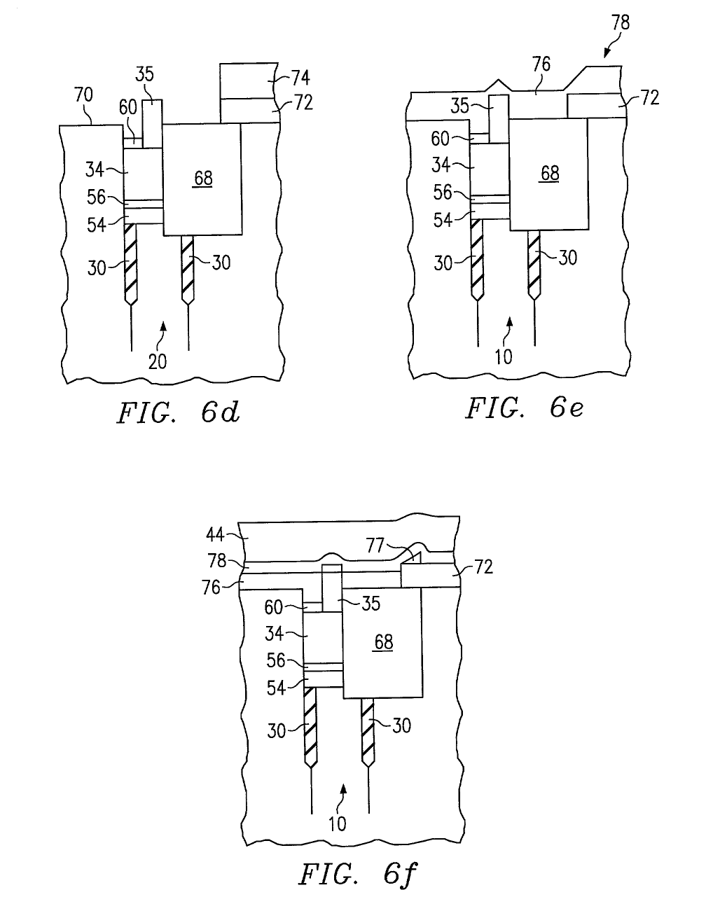

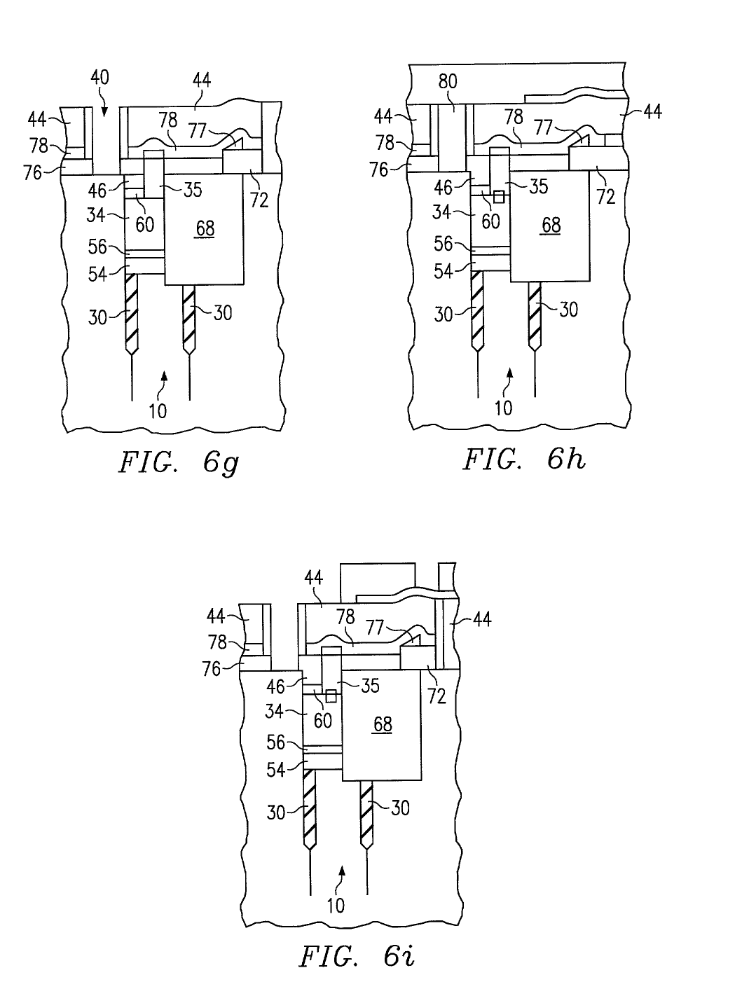

FIG. 5a is a top-down view of deep trench 20 prior to the formation of isolation trench (IT) 10. Note that, as formed, deep trench 20 extends beyond the boundaries of overlying active area 6 and extends into what will become the isolation trench region. This is illustrated by the crosshatched regions 64. FIG. 5b illustrates the deep trench 20 after the isolation trench has been etched. Crosshatched regions 64 and the surrounding silicon have been etched, leaving active region 6 and deep trench 20 being bounded by an isolation trench 10 on either side. Dotted line 6-6 illustrates the crosssectional view provided in FIGS. 6a through 6i. Note that the cross-sectional view is in two perspectives, half of the cross-sectional view (the portion of FIGS. 6a through 6i to the left of the dotted vertical line) is taken along the axis of bit line region, also known as the AA region. This corresponds to the horizontal portion of dotted line 6-6 in FIG. 5b. The other half of the cross-sectional view (the portion of FIGS. 6a through 6i to the right of the dotted vertical line) is taken perpendicular to the bit line region. This corresponds to the vertical portion of dotted line 6-6 in FIG. 5b. Careful attention to the perspective provided in this way will aid in understanding the following description.

To continue with the description of the processing steps, the portion of the deep trench 20 underlying the bit line region, or active region, is covered by hard mask 62. The portions lying outside the active regions are and the surrounding silicon is not covered by the hard mask, however. As shown in FIG. 6a, the exposed regions, including portions 64 of the deep trench, are etched, resulting in isolation trench 10. This step effectively truncates the upper and lower edges of deep trench 20 and removes regions 64 that were formed in the region of the isolation trench. Isolation trench 10 is preferably formed by an oxidation followed by a one or more step HDP fill (e.g. deposition, etch back, deposition). As illustrated in FIG. 6b, the isolation trench is filled with an insulating oxide 68, using an HDP process or other well known alternative. The isolation trench oxide 68 is then planarized using, e.g. AV planarization, CMP, or the like. Hard mask 62 is then removed and the trench oxide 68 and nitride spacer 60 are planarized to the top of nitride layer 52, preferably using a CMP step.

In FIG. 6c, the nitride layer 52 and nitride spacer 60 have been substantially removed to leave nitride cap 48 (also shown in FIG. 2). This removal process is a timed etch involving preferably hot phosphor or alternatively a dry etch nitride selective to oxide and poly. During this step isolation trench oxide 68 is also etched back somewhat due to the need to perform an oxide etch prior to the nitride etch (in order to remove any residual oxide layer on the nitride surface). This results in the gate polysilicon stud 35 sticking out above the surface of the nitride and oxide layers, as shown in FIG. 6c. A sacrificial oxide layer is then formed (not shown) followed by implantation of the doped regions for the planar support circuits. Additionally, the doped junction regions 38 for the vertical gate transistor 22 are formed by ion implantation in this step as well, although not shown in FIGS. 6. After the implantation step, the sacrificial oxide layer is removed prior to further processing. It bears noting that during each thermal step, such as annealing after the implantation, and the like, the polysilicon layer 54 within the trench outdiffuses somewhat. This outdiffusing of the doped polysilicon into the bulk silicon surrounding the trench is what results in the buried strap or doped junction 28 (shown in FIG. 2).

As shown in FIG. 6d, a planar device gate oxide 70 is then formed, followed by polysilicon layer 72. Polysilicon layer 72 will form the gate poly in the support. In FIG. 6d, the polysilicon layer 72 is shown as having been patterned, which one skilled in the art will recognize as involving covering the surface of the device with the polysilicon layer and then patterning the layer using well known photolithographic and etching processes (e.g. poly selective to oxide). Etch array (EA) mask 74 is shown in FIG. 6d in phantom line to show the masking process. The purpose of the EA mask 74 is to expose the active area and deep trench regions to the polysilicon etch, while covering the support regions (where the planar devices are formed), such that the resulting polysilicon layer 72 covers only the support regions. EA mask 74 is subsequently stripped away.

Thick oxide layer 76 is then deposited using an HDP process or alternatively a TEOS deposition or other available deposition technique. This thick oxide layer 76 is patterned using an etch support (ES) mask 78, shown in phantom line in FIG. 6e. The ES mask 78 covers the array regions and exposes the support regions, hence the oxide layer 76 is etched away in those regions where polysilicon layer 72 had been formed in the previous processing steps and remains only over the active areas. Note that, as shown in FIG. 6e, there may be some overlap between the resulting polysilicon layer 72 and the thick oxide layer 76. Thick oxide layer 76 is then planarized, either through a controlled etch in case of a non-conformal deposition like HDP, or through a CMP step, resulting in a planar top oxide surface below the level of gate polysilicon stud 35 and polysilicon layer 72, as shown in FIG. 6f. Note that a portion of thick oxide layer 76, designated as 77, may remain on polysilicon layer 72. This is an artifact of the processing steps because the oxide layer 76 is not etched back entirely in the active regions, hence it will not be etched back entirely where it overlaps with the polysilicon layer. Although this feature 77 is not desirable because it decreases the planarity of the resulting structure (as illustrated in FIGS. 6f through 6i), it does not degrade performance or yield appreciably. Note that the feature 77 is a significant factor in the gate stack etch, because remaining oxide is blocking the etch. Therefore a cover ring around the array is preferably used, so that no gate etch is done perpendicular to this feature. The masks EA and ES have their shapes always within this cover ring. All wordlines in the array are electrically and structurally isolated from the cover ring and have to be pulled out of the array via a subsequent wiring level.

After planarizing the thick oxide layer 76, an oxide clean step is performed to remove any oxide that has been formed over the gate polysilicon 35. This is preferably a wet etch process, such as HF. Subsequent to the oxide clean up, the word line conductor stack can be formed. As discussed above, the word lines are preferably a multi-layer stack of polysilicon 140 and tungsten 42, as shown in FIG. 2. Alternatively, the conductors can be formed of a single layer or a combination of layers comprising polysilicon, tungsten, tungsten nitride, tungsten silicon, tantalum nitride, silicided silicon or other well known alternatives. Nitride cap 44 is then formed over the conductor stack using well known nitride deposition processing, such as CVD. Note the hump formed in the word line caused by the oxide artifact 77. Care must be taken to ensure that the word line makes good coverage over this region.

In FIG. 6g, formation of the wordline/support gate stack is illustrated. This process is well known in the art. Oxide and nitride spacers are applied to the gate stack. Device implants according to the needs of the transistors can be applied in the supports. In FIG. 6h, the structured gate stack is filled with BPSG and the surface is planarized by CMP to the cap layer of the stack 44. A nitride layer is deposited and opened by lithography and nitride etch over the array. An additional oxide layer, e.g., TEOS is deposited. With a selective etch oxide to nitride, the bitline together with the first support wiring is structured with one bitline M0 mask and etched. In the support area, the etch is stopped on the nitride layer, whereas the etch reaches drain region 38 in the array for the bitlines. Note the oxide spacer 46 and nitride cap 60 prevent the bitline contact (and hence the bit line) from contacting the gate poly, even in the event of some mis-alignment of the M0 mask. In FIG. 6i, the bitline with the contacts 40 is filled with a conductor. The bit lines can be formed of a single conductor layer, or a combination of conductor layers, such as polysilicon, tungsten, tungsten nitride, tungsten silicon, tungsten nitride, and the like in a more step process.

An advantage of the preferred embodiments is that the gate length can be doubled without adversely impacting the on current to off current ratio because the gate width is also effectively doubled through use of the double gate on both sides of the trench.

A further advantage of the preferred embodiments is that the disclosed structure allows for a 2F by 2F pass transistor (i.e. the gate length is twice the minimum ground rule length, but the gate width is also twice the ground rule).

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For instance, exemplary insulative materials have been disclosed, such as oxide and nitride, although in some instances these materials can be substituted for each other, or other insulative materials could be employed. Conductive materials have also been disclosed, but it is within the scope of the present invention to employ other combinations of the disclosed or other conductive materials, such as now commonly employed in the art or subsequently developed. Certain spacings and dimensions have been disclosed regarding the currently contemplated best mode of the invention. These dimensions are not intended to be limiting in any manner and the present invention contemplates larger or smaller devices. Additionally, the present teaching may be applicable to other semiconductor materials and process, such as Germanium, Gallium-Arsenide, other III-IV materials, or other semiconductor materials. Other etch processes than specifically described above are within the scope of the present invention, including reactive ion etching (RIE), wet etching, dry etching, plasma etching, and the like. Likewise, the deposition techniques described herein are exemplary, rather than limiting and the present invention is broad enough to include other deposition techniques such as CVD, PVD, PEVD, thermal oxidation, and the like. It is intended that the appended claims encompass any such modifications or embodiments.

What is claimed is:

1. A memory device comprising:
a memory cell array, the array including a plurality of memory cells arranged in rows and columns, the rows being separated by isolation trenches;
each memory cell comprising:
a trench having a capacitor formed therein;
a first pass transistor having a first doped region formed from an outdiffusion of doped material formed within the trench, a second doped region formed adjacent the trench; and gate region formed within the trench, and a gate oxide formed on a sidewall of the trench; and
a second pass transistor having a first doped region formed from an outdiffusion of doped material from within the trench, a second doped region formed adjacent the trench, sharing the gate region formed within the trench with the first pass transistor, and having a gate oxide formed on a sidewall of the trench.

2. The memory device of claim 1 further comprising a word line connected to the gate region of the first and second pass transistors and a bit line connected to the second doped regions of the first and second pass transistors.

3. The memory device of claim 1 further comprising a second memory cell adjacent the first memory cell and comprising a first and second pass transistor, and wherein the first pass transistor of the first memory cell and the first pass transistor of the second memory cell share a common second doped region.

4. The memory device of claim 1 wherein the first and second doped regions are formed of n-type material formed within p-type semiconductor material.

5. The memory device of claim 1 further comprising:
a trench top oxide formed within the trench between the capacitor and the gate polysilicon.

6. The memory device of claim 1 wherein the first doped region outdiffuses from a doped polysilicon material formed within the trench.

7. The memory cell of claim 1 wherein the first pass transistor and second pass transistor has a gate length and a gate width, and the gate length is equal to the gate length for the first and second pass transistors.

8. The memory cell of claim 2 wherein the word line and bit line are formed of one or more conductive layers comprised of one or more of polysilicon, tungsten, tungsten nitride, and tungsten silicon.

9. The memory device of claim 1 wherein the memory cell array is formed in a semiconductor substrate and further comprising:
a second memory cell adjacent a first memory cell and comprising a first and second pass transistor, wherein the first pass transistor of the first memory cell and the first or second pass transistor of the second memory cell share a common bulk contact in the semiconductor substrate.

10. The memory device of claim 1 further comprising a self-aligned insulator region formed above the trench providing electrical isolation between the gate region formed within the trench and a the bitline contacting the second doped region.

11. The memory device of claim 10 wherein the insulator region is formed of silicon nitride and/or silicon oxide.

12. The memory device of claim 2 further comprising a passing word line adjacent the word line and an insulator layer formed between the passing word line and the second doped region formed adjacent the trench.

13. The memory device of claim 1 wherein the memory cell array comprises an array of trenches, the array of trenches being arranged in a regularly spaced pattern.

14. A method of forming a memory cell, comprising:
forming a buried plate within a semiconductor substrate;
forming a deep trench having sidewalls within an active area of a semiconductor substrate;
forming an dielectric along the sidewalls of the deep trench;
forming a trench collar along a middle portion of the deep trench;
filling the trench partly with doped polysilicon, wherein the dopant in the polysilicon is outdiffused into the active area from the trench in those portions not bound by the trench collar during subsequent processing steps;
forming a trench top oxide on the polysilicon;
forming a gate dielectric on the vertical sidewalls of the trench
filling the trench with a gate polysilicon above the trench top oxide;
forming a first doped region adjacent one sidewall of the trench and a second doped region adjacent another sidewall of the trench;
forming a contact to the gate polysilicon and connecting the gate polysilicon to a word line; and
forming a contact to the first and second doped regions and connecting the first and second doped regions to a bit line.

15. The method of claim 14 further comprising etching away a portion of the active area to form an isolation trench on each side of the active area and the deep trench and filling the isolation trench with an insulator.

16. The method of claim 14 wherein the step of forming an oxide along the sidewalls of the deep trench comprises:
forming a first oxide along a lower portion of the sidewalls of the deep trench; and
subsequently forming a gate oxide along an upper portion of the sidewalls of the deep trench.

17. The method of claim 15 wherein the active region is divided into a plurality of active regions by isolation trenches and deep trenches.

18. The method of claim 14 wherein the outdiffusion of the dopant in the polysilicon forms a third and fourth doped region, and where the first and third doped regions form the drain and source, respectively of a first pass transistor and the second and fourth doped region form the drain and source, respectively, of a second pass transistor, the first and second pass transistors sharing a common gate.

19. A memory circuit comprising:
a capacitor, the capacitor being formed in a lower portion of a trench;
a logical pass transistor having a vertical gate formed within an upper portion of the trench, and comprising:
first and second source regions;
first and second drain regions; and
a single gate, having a first gate oxide adjacent the first source and drain regions and a second gate oxide adjacent the second source and drain regions.

20. The memory circuit of claim 19 wherein the first and second source regions are formed form outdiffusing doped material from within the trench.

21. The memory circuit of claim 19 wherein the trench is between five microns and ten microns in depth.

22. The memory circuit of claim 20 wherein the doped material is doped polysilicon.

23. The memory circuit of claim 19 wherein the vertical gate of the logical pass transistor has a gate width that is equal to the gate length.

24. The memory circuit of claim 19 wherein the trench is formed within and interrupts an active region of the silicon that underlies a bit line, and further comprising an isolation trench formed on either side of the active region.

25. The memory circuit of claim 19 wherein the first and second source regions and the first and second drain regions and the gate polysilicon are formed of n-type semiconductor material and the active region is formed of p-type semiconductor material.
